(19) United States
(12) Patent Application Publication
(10) Pub. No.: US 2026/0176132 A1
(43) Pub. Date: Jun. 25, 2026

(54) SILICON-METAL COMPOSITE MICRO-ELECTRO-MECHANICAL SYSTEM-BASED MATERIAL ATMOSPHERIC CORROSION SENSOR, PREPARATION METHOD THEREFOR, AND MATERIAL ATMOSPHERIC CORROSION DETECTION EQUIPMENT

(71) Applicant: University of Science and Technology Beijing, Beijing (CN)

(72) Inventors: Xiaojia YANG, Beijing (CN); Qing LI, Beijing (CN); Renzheng ZHU, Beijing (CN); Xinyu WANG, Beijing (CN); Da WEI, Beijing (CN)

(73) Assignee: University of Science and Technology Beijing, Beijing (CN)

(21) Appl. No.: 19/390,450

(22) Filed: Nov. 14, 2025

(30) Foreign Application Priority Data
Dec. 19, 2024 (CN) 202411875662.3

(51) Int. Cl. B81C 1/00; B81B 7/00

(52) U.S. Cl. CPC B81C 1/00714; B81B 7/0077; B81B 2201/0214; B81B 2203/0315; B81B 2203/0353; B81B 2203/04; B81B 2207/015; B81C 2201/0133; B81C 2201/0156; B81C 2201/0181; B81C 2201/019; B81C 2203/031

(57) ABSTRACT

Provided are a silicon-metal composite MEMS-based material atmospheric corrosion sensor, a preparation method therefor, and material atmospheric corrosion detection equipment. The sensor includes a cathode-anode module and a cavity structure module. The cathode-anode module includes a first substrate, a metal anode and a metal cathode which are arranged on a surface of the first substrate and are independent from each other; the cavity structure module includes a second substrate, the second substrate is provided with a recess portion and a through hole. The recess portion extends from a first side of the second substrate to an opposite second side, and the through hole extends from a surface of the second side to the bottom of the recess portion; and the surface of the first side abuts against the surface of the first substrate, and the metal cathode and the metal anode are arranged in the recess portion.

### CROSS-REFERENCE TO RELATED APPLICATION

This patent application claims the benefit and priority of Chinese Patent Application No. 202411875662.3 filed with the China National Intellectual Property Administration on Dec. 19, 2024, the disclosure of which is incorporated by reference herein in its entirety as part of the present application.

### TECHNICAL FIELD

The present disclosure relates to the technical field of material corrosion sensors, and in particular to a silicon-metal composite Micro-Electro-Mechanical System (MEMS) material atmospheric corrosion sensor, a preparation method therefor, and material atmospheric corrosion detection equipment.

### BACKGROUND

Material corrosion is one of the important reasons resulting in the failure of metal structural components, especially in the microelectronics industry, the corrosion failure of electronic device materials directly threatens the service life of industrial equipment, and even cause information security problems in serious cases. Device-level material corrosion monitoring technology is one of key technologies for analyzing the causes of device corrosion failure, determining the state of material corrosion failure, and predicting the corrosion failure life of devices. The conventional corrosion monitoring technology employs a mechanical structural-type sensor, which cannot achieve device-level material corrosion monitoring, and has the characteristics of large volume, low precision, high cost, and difficult batch fabrication, resulting in incapability of large-scale monitoring of corrosion failure of the electronic devices. With the continuous progress of science and technology and the continuous development of society in recent years, the significant advancements in MEMS technology is achieved and MEMS sensors have accordingly developed significantly, which are widely used in a diverse range of fields including automotive, security, biomedicine, power systems, smart buildings, forest fire prevention, smartphones, and the Internet of Things (IoT). However, MEMS sensors suitable for material corrosion have been in an undeveloped state due to technical reasons. Therefore, the present disclosure uses micro-mechanical manufacturing process to achieve the device-level material corrosion monitoring, which is crucial for the development of material corrosion big data technology and the MEMS sensor.

### SUMMARY

An objective of the present disclosure is to provide a silicon-metal composite MEMS material atmospheric corrosion sensor, a preparation method therefor, and material atmospheric corrosion detection equipment, thereby solving the problem that an existing mechanical atmospheric corrosion sensor is poor in stability, low in repeatability, and difficult in batch fabrication.

To achieve the objective, the present disclosure employs the technical solution as follows.

A silicon-metal composite MEMS-based material atmospheric corrosion sensor includes a cathode-anode module and a cavity structure module;
the cathode-anode module comprises a first substrate, a metal anode and a metal cathode, the metal anode and the metal cathode are arranged on a surface of the first substrate and are independent from each other;
the cavity structure module comprises a second substrate, the second substrate is provided with a recess portion and a through hole, the through hole is configured for communicating with atmosphere of a test environment, the recess portion extends from a first side of the second substrate toward an opposite second side of the second substrate, and the through hole extends from a surface of the second side to a bottom of the recess portion;
the surface of the first side abuts against the surface of the first substrate, and the metal cathode and the metal anode are arranged in the recess portion;
a material of the metal anode is a material of a metal to be tested, and a material of the metal cathode is coupled with the material of the metal to be tested; and
a spacing between the metal anode and the metal cathode is 10 μm-100 μm.

When the spacing is too small, the deposition of conductive corrosion products or particles with conductive properties in the air can easily lead to a short circuit. Excessive spacing makes the sensor insensitive to environment corrosive changes, which greatly reduces the sensitivity of the sensor. Considering comprehensively, the spacing between the metal anode and the metal cathode should be controlled between 10 microns and 100 microns.

Preferably, the first substrate and the second substrate are respectively and independently a silicon wafer or glass.

Preferably, the first substrate is a silicon wafer, the second substrate is glass, the material of the metal to be tested is stainless steel, and the material of the metal cathode is copper.

The present disclosure further provides a preparation method for the silicon-metal composite MEMS-based material atmospheric corrosion sensor, including the following steps:
adhering the material of the metal to be tested that is sheet-shaped with the first substrate to obtain a substrate-metal composite sheet;
applying photoresist on a surface of the substrate-metal composite sheet, and then carrying out exposure, development and fixation by means of a mask with a metal anode pattern to form a metal anode target pattern; etching by mean of the metal anode target pattern until the first substrate is exposed, and removing residual photoresist to obtain a first composite sheet;
applying the photoresist on one side, with the metal anode, of the first composite sheet, then carrying out exposure, development and fixation by means of a mask with a metal cathode pattern to form a metal cathode target pattern to obtain a second composite sheet; sputtering a cathode material on the second composite sheet by using a sputtering method, and then removing residual photoresist and residual cathode material from the second composite sheet to obtain the cathode-anode module;
applying the photoresist on the first side of the second substrate, then carrying out exposure, development and fixation by means of a mask with a recess portion pattern to form a recess portion target pattern; etching by means of the recess portion target pattern until the recess portion is formed; removing residual photoresist; then applying the photoresist on the second side, carrying out exposure, development and fixation by means of a mask with a through hole pattern to form a through hole target pattern; etching by means of the through hole target pattern until the through hole is formed, and removing residual photoresist to obtain the cavity structure module; and
disposing the metal anode and the metal cathode of the cathode-anode module in the recess portion of the cavity structure module, and then connecting a surface of the first side of the second substrate to the surface of the first substrate.

Preferably, the adhering is carried out by using a polydimethylsiloxane two-component adhesive.

Preferably, in the step of etching by mean of the metal anode target pattern, an etching agent includes:
2.7-5.4 mol/L of HCl, 4.4-7.4 mol/L of hydrogen peroxide, 1-10 g/L of corrosion inhibitor, 20-50 g/L of dispersing agent, and 5-10 g/L of hydrogen peroxide stabilizer.

Preferably, the connecting includes:
carrying out chemical cleaning and activation treatment on the surface of the first side and the surface of the first substrate by using a wet chemical treatment method; and
connecting the first substrate to a positive terminal of a power supply, connecting the second substrate to a negative terminal of the power supply, heating to 300° C.-500° C., applying a bias voltage of more than 500 V, and enabling the first substrate and the second substrate to be bonded by a generated electrostatic force.

The present disclosure further provides material corrosion atmospheric corrosion equipment, including the silicon-metal composite MEMS-based material atmospheric corrosion sensor.

Preferably, the material corrosion atmospheric corrosion equipment further includes a signal processing module electrically connected to the silicon-metal composite MEMS-based material atmospheric corrosion sensor, where the signal processing module comprises an Application Specific Integrated Circuit (ASIC) chip with micro-current and micro-voltage detection ability.

Preferably, the material atmospheric corrosion equipment further includes a lead frame structure capable of bearing the silicon-metal composite MEMS-based material atmospheric corrosion sensor and the ASIC chip.

Compared with the prior art, the present disclosure has beneficial effects as follows.

In the silicon-metal composite MEMS-based material atmospheric corrosion sensor provided by the present disclosure, a material corrosion electrochemical sensitive material is disposed on a non-metallic substrate, and a material corrosion sensitive element and an electric quantity detection module are integrated as a whole, which optimizes the performance of the material corrosion sensor, and can greatly improve the sensitivity, reliability and consistency of the material corrosion sensor.

In the preparation process of the silicon-metal composite MEMS-based material atmospheric corrosion sensor provided by the present disclosure, the silicon wafer and the metal material are adhered together, then the metal the etched by using an etching method to form a working electrode (anode) of metal to be tested for corrosion monitoring, and a silicon substrate is subjected to sputtering to form a counter electrode and a reference electrode (cathode). The problem of difference in composition and microstructure between a conventional sputtered metal sensor and a machined sensor can be solved, and the problems of small size, homogenization, high stability and batch fabrication are also solved. The related technology can promote wider application of the MEMS-based atmospheric corrosion sensor in various high-precision material atmospheric corrosion online monitoring scenarios.

The material atmospheric corrosion detection equipment provided by the present disclosure includes micromachining technology and microelectronics technology. The material corrosion is converted into signal changes such as capacitance, resistance and current through MEMS chips; and the signals such as capacitance, resistance and current are converted into electrical signals through the ASIC chip, thereby implementing the function of the MEMS-based corrosion sensor of converting the material corrosion signal into the electrical signals.

### BRIEF DESCRIPTION OF THE DRAWINGS

To describe the technical solution of embodiments of the present disclosure more clearly, the accompanying drawings used for the description of the embodiments of the present disclosure are briefly introduced below. It should be understood that the following accompanying drawings only show some embodiments of the present disclosure, and therefore should not be regarded as limiting the scope of the present disclosure.

FIG. 1 is a diagram of a silicon wafer and a metal sheet that are adhered;

FIG. 2 is a diagram of preparation process of a MEMS sensor;

FIG. 3 is a diagram of a cavity structure;

FIG. 4 is a front view of a MEMS sensor;

FIG. 5 is a top view of a MEMS sensor; and

FIG. 6 is a perspective view of a MEMS sensor.

### REFERENCE NUMERALS

1—metal anode; 2—silicon wafer; 3—Polydimethylsiloxane (PDMS) adhesive; 4—metal cathode; 5—glass sheet; 6—through hole.

### DETAILED DESCRIPTION OF THE EMBODIMENTS

Implementations of the present disclosure are described in detail below with reference to specific embodiments, but those skilled in the art should understand that the following embodiments are only used to illustrate the present disclosure and should not be regarded as limiting the scope of the present disclosure. Unless otherwise specified in the embodiments, the procedures are carried out in standard conditions or according to the instructions of the manufacturers. All reagents and instruments used without specifying the manufacturers are conventional products that are commercially available.

### Embodiment 1

This embodiment provides a silicon-metal composite MEMS-based material atmospheric corrosion sensor including a cathode-anode module and a cavity structure module. The cathode-anode module includes a silicon wafer, and a metal anode and a metal cathode which are arranged on a surface of the silicon wafer and are independent from each other. The cavity structure module includes a glass sheet, the glass sheet is provided with a recess portion and a through hole configured for communicating with atmosphere of a test environment. The recess portion extends from a first side of the glass sheet to an opposite second side of the glass sheet, and the through hole extends from a surface of the second side of the glass sheet to the bottom of the recess portion. The surface of the first side of the glass sheet is bonded to the surface of the silicon wafer, and the metal cathode and the metal anode are arranged in the recess portion.

A preparation method for the silicon-metal composite MEMS-based material atmospheric corrosion sensor is as follows.

### (1) Preparation of Metal Anode 1

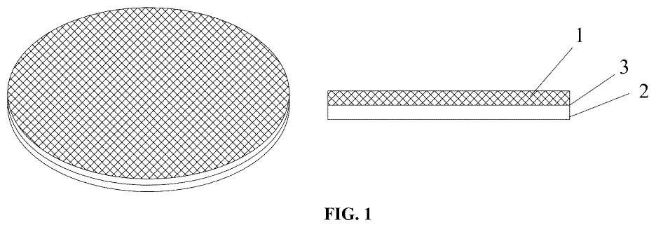

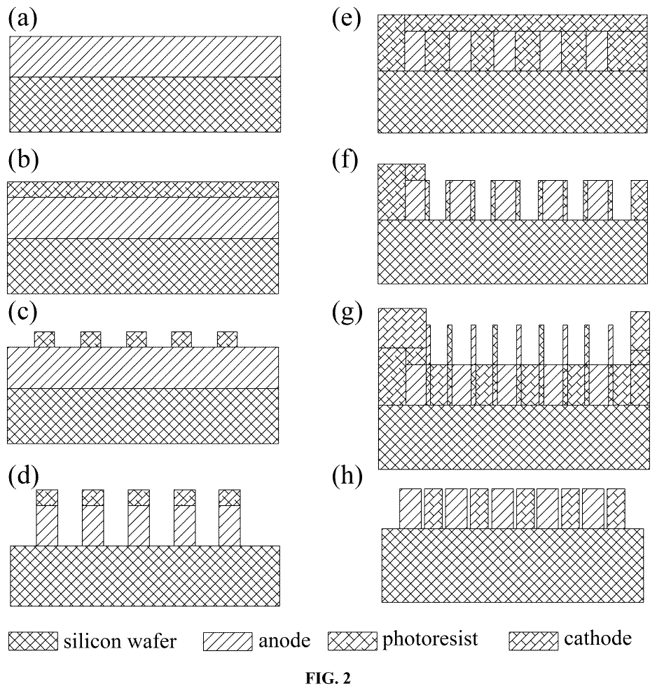

5.1. FIG. 1 is an adhesion diagram of a silicon wafer and a metal sheet that are adhered. As shown in FIG. 1, a silicon wafer 2 is employed as a substrate material. Specifically, a 4-inch (¢100.84 mm) wafer is used as a substrate material. 316L stainless steel is used as a metal anode material, the 316 L stainless steel is cut into discs of @100.84 mm×300 μm. The surface of the stainless steel is progressively ground with SiC abrasive paper until the surface of the stainless steel is ground with SiC abrasive paper of 5000 #, progressively polished with Al₂O₃ polishing paste to a particle size of 1μ, and finally cleaned with deionized water and high-purity alcohol, dried for later use.
5.2. polydimethylsiloxane (PDMS) adhesive 3 (polydimethylsiloxane two-component adhesive) is used to bond the silicon wafer 2 and the 316L stainless steel. Firstly, a component A (PDMS prepolymer) and a component B (curing agent) in a weight ratio of 10:1 are completely mixed to form a mixed solution with moderate viscosity, then the mixed solution is evenly coated on the surfaces of silicon wafer and the 316 L stainless steel, and the silicon wafer and the 316 L stainless steel are concentrically bonded and then placed on a heating table and cured for 35 minutes, so that the PDMS adhesive is fully cured, where a temperature of the heating table is adjusted to 100° C.
5.3. An acidic cleaning solution is prepared from 30% hydrochloric acid and ultrapure water in a volume ratio of 1:1 and used to remove oxide on the surface of 316L stainless steel, then the silicon-316L stainless steel sheet is washed with a large amount of deionized water, and the silicon-316L stainless steel sheet is spin-dried by means of high-speed spin-drying equipment, where the spin-drying process is performed for 300 s.
5.4. With reference to FIG. 2, the silicon wafer 2 is coated with SU-8 semiconductor ultraviolet photoresist. The SU-8 photoresist is evenly spin-coated on the 316L stainless steel at a rotating speed of 1000 r/min, where a spin-coating thickness is controlled at 120 microns. The silicon wafer is heated at 80-120° C. for 120 s by a uniform heating plate, fully dried and then transferred to a lithography machine, and a mask of an anode metal material is loaded on the lithography machine for exposure, where the exposure is performed with an ultraviolet radiation dose of 200 mJ/cm² for 10 seconds.
5.5. SU-8 developing solution is used for sufficient development until a pattern of the anode metal material is clearly and completely presented.
5.6. Afterwards, the stainless steel is etched by a stainless steel etching solution. The recommended component solutes of the stainless steel etching solution are as follows: 800 g/L of FeCl₃, 100 mL/L of HCl, 100 mL/L of HF, 8 g/L of H₃PO₄, and 20 g/L of CuSO₄, and an etching depth is a thickness of the stainless steel.
5.7. After sufficient etching, the surface of the silicon-316L stainless steel sheet is sufficiently cleaned with ultrapure water, and then the photoresist is peeled and cleaned by using an SPM (Sulfuric acid-Peroxide Mixture) cleaning technology.

### (2) Preparation of Metal Cathode 4

5.8. With reference to FIG. 2, Step 5.4 is repeated, with a difference that a mask of a cathode metal material is loaded onto a lithography machine for exposure.
5.9. Step 5.5 is repeated, with a difference that a pattern of the cathode metal material is clearly and completely presented.
5.10. A cathode electrode required for material corrosion electrochemical measurement is formed by using a magnetron sputtering method. In this embodiment, a high-purity Cu target (99.999%) is used, a working pressure is 0.5 Pa, a target voltage is 450 V, a target current density is 20 mA/cm², and a deposition rate is approximately 1.5 nm/min.
5.11. The photoresist on the metal anode and the metal cathode is peeled by using the SPM cleaning technology, and the residual metal is cleaned.

A spacing between the metal anode and the metal cathode is 50 μm.

### (3) Preparation of Cavity Structure

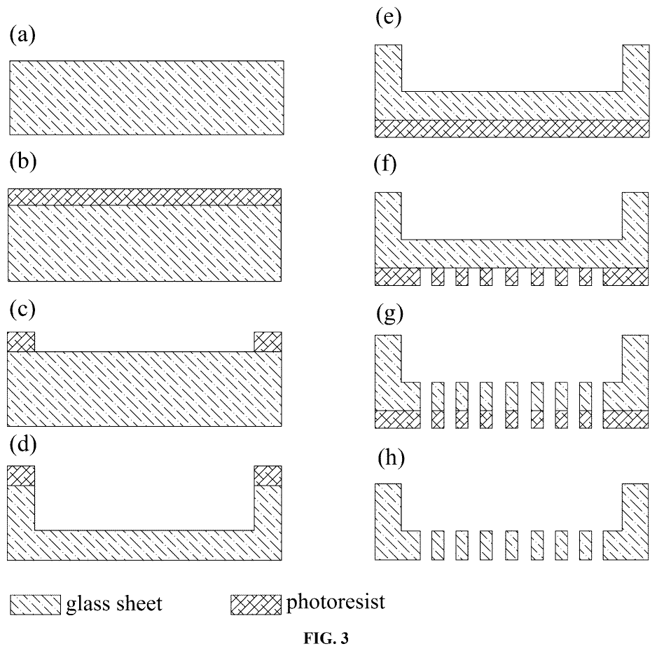

5.12. With reference to FIG. 3, a 4-inch (φ100.84 mm) glass sheet 5 is used as a cavity structure material, and the surface of the glass sheet is cleaned with deionized water. Afterwards, a cleaning solution composed of 25% hydrogen peroxide, 25% ammonia water and pure water in a volume ratio of 1:1:20 is used to clean the glass sheet for about 260 s, and then the cleaning solution composed of 30% hydrochloric acid, 25% hydrogen peroxide and pure water in a volume ratio of 1:1:20 is used to continue cleaning the glass sheet for 250 s. Afterwards, the silicon wafer is washed with a large amount of deionized water, and then is dried with high-speed spin-drying equipment, where a spin-drying process lasts for 300 s.
5.13. Step 5.4 is repeated with a difference that a mask of a cavity structure is loaded onto a lithography machine for exposure.
5.14. Step 5.5 is repeated, with a difference that a pattern of the cavity structure is clearly and completely presented.
5.15. The glass sheet is etched by using a deep silicon etching method to remove an exposed substrate region. The exposed substrate region is etched downwards to form a cavity.
5.16. The photoresist is peeled and cleaned by using the SPM cleaning technology.
5.17. The cleaning process for the glass sheet in Step 5.12 is repeated.
5.18. Step 5.4 is repeated, with a difference that the photoresist is coated on a reverse side of the glass sheet and a mask of the cavity structure is loaded onto the lithography machine for exposure.
5.19. Steps 5.15 to 5.17 are repeated, with a difference that a back surface of the glass sheet is etched to form a through hole 6, so that atmospheric environment factors can enter a surface of the sensor after passing through the glass sheet.

### (4) Silicon-Glass Sheet Anodic Bonding

5.20. At first, the silicon-316L stainless steel sensor structure and the cavity structure are subjected to chemical cleaning and activation treatment by using a wet chemical treatment, where solution for a wet chemical treatment is RCA1(NH₄OH:H₂O₂:H₂O=1:1:5) solution, the silicon wafer is cleaned with the solution to remove organic pollution from the silicon surface. RCA2(HCl:H2O2:H2O=1:1:6) solution is used for surface activation to treat the ion and metal pollution at a silicon interface, increasing electrostatic tension at a silicon-glass sheet interface.
5.21. The silicon sheet 2 is connected to a positive terminal of a power supply, the glass sheet 5 is connected to a negative terminal of the power supply, the temperature is raised to 300-500° C., a bias voltage of more than 500 V is applied, so that the silicon wafer 2 and the glass sheet 5 are bonded by a generated electrostatic force.

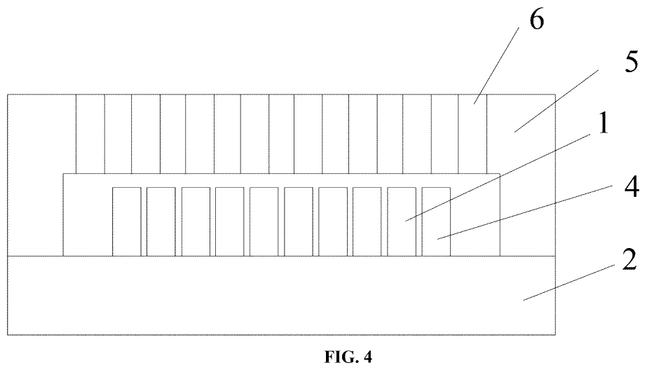

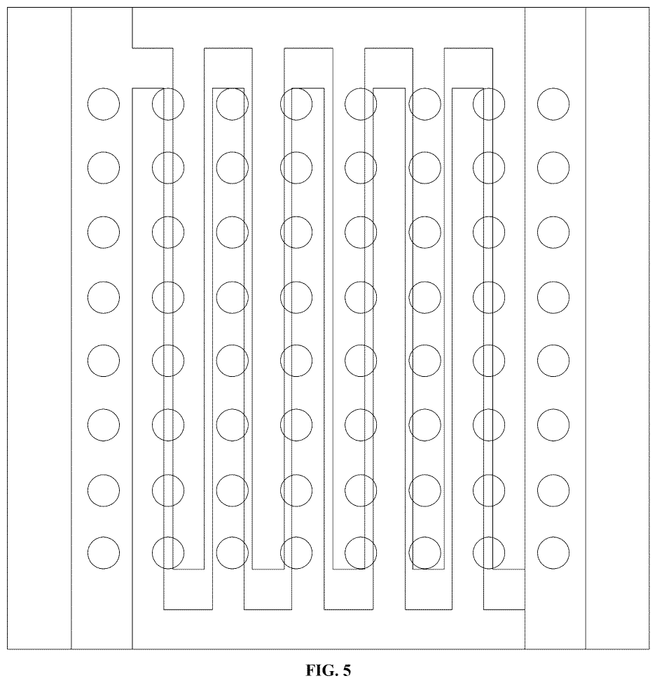

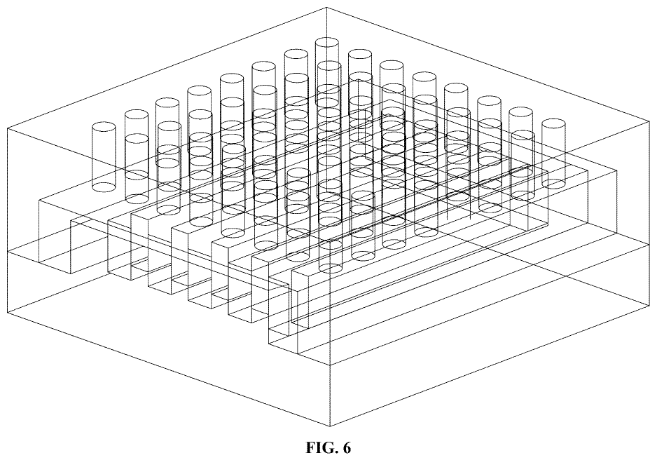

The obtained MEMS sensor is shown in FIG. 4, FIG. 5 and FIG. 6.

In other embodiments, the cathode-anode module and the cavity structure module may also be connected by coating a titanium adhesive layer on the surface of the cavity structure or arranging solder.

This embodiment further provides material atmospheric corrosion detection equipment, with a specific preparation method as follows.

### (5) Lead Bonding

5.22. The obtained MEMS sensor and a Ni—Pd—Ag—Au frame are subjected to lead bonding. Plasma cleaning equipment is used to carry out plasma cleaning on the lead frame and the MEMS corrosion sensor before lead bonding. The cleaning process is as follows: argon is introduced into the equipment, the sample is put into a plasma region, where a pressure is controlled at 200 Pa, a power density is 8 Wcm², and the cleaning lasts for 10 minutes. Afterwards, the MEMS chip and the Ni—Pd—Ag—Au frame are subjected to lead bonding by using a copper bonding process.

In addition, the material atmospheric corrosion detection equipment further includes a signal processing module which is a specific ASIC chip with micro-current and micro-voltage detection ability. In this embodiment, MAX4080SASA+T current high-precision detection amplifier IC chip is selected to detect current and voltage signals generated by a material atmospheric corrosion sensitive element when corroded by the atmosphere and to convert the current and voltage signals into material corrosion rate electrical signals. The ASIC chip is placed on the Ni—Pd—Ag—Au frame and electrically connected to the MEMS corrosion sensor.

Finally, the MEMS material corrosion sensor and ASIC signal processing module are encapsulated with a plastic packaging material.

The present disclosure provides a silicon-metal composite MEMS-based material atmospheric corrosion sensor and a preparation method therefor. A MEMS corrosion sensor with a planar structure is formed by etching to form a metal anode electrode with the same structural material and combining the metal anode electrode with a cathode electrode prepared by sputtering. Combined with an ASIC micro-current processing chip with the MEMS corrosion sensor, the detection of atmospheric corrosion of the metal material and tiny corrosion current formed between the anode and the cathode is achieved. The detection of the corrosion signal is implemented through the ASIC amplifier circuit and digital-to-analog conversion. Therefore, the sensor preparation technology with the material consistent with the structural composition and microstructure of bulk metal is achieved, and the issue of difference between the actual corrosion mechanism and the corrosion mechanism of the metal to be tested caused by inconsistency of material microstructures caused by sputtering metal is eliminated. In addition, the batch preparation of micro-sensors is achieved through MEMS technology, which greatly improves the consistency and linearity of the material corrosion sensor.

Finally, it should be noted that the foregoing embodiments are merely used to describe the technical solution of the present disclosure, rather than limitation. Although the present disclosure is described in detail with reference to the foregoing embodiments, a person of ordinary skill in the art should understand that: the technical solutions described in the foregoing embodiments may still be modified, or some technical features or all technical features thereof may be equivalently replaced. These modifications or replacements shall not cause the essential nature of the corresponding technical solution to deviate from the scope of the technical solutions of embodiments of the present disclosure.

What is claimed is:

1. A silicon-metal composite Micro-Electro-Mechanical System (MEMS)-based material atmospheric corrosion sensor, comprising a cathode-anode module and a cavity structure module, wherein
the cathode-anode module comprises a first substrate, a metal anode and a metal cathode, the metal anode and the metal cathode are arranged on a surface of the first substrate and are independent from each other;
the cavity structure module comprises a second substrate, the second substrate is provided with a recess portion and a through hole, the through hole is configured for communicating with atmosphere of a test environment, the recess portion extends from a first side of the second substrate toward an opposite second side of the second substrate, and the through hole extends from a surface of the second side to a bottom of the recess portion;
the surface of the second side abuts against the surface of the first substrate, and the metal cathode and the metal anode are arranged in the recess portion;
a material of the metal anode is a material of a metal to be tested, and a material of the metal cathode is coupled with the material of the metal to be tested; and
a spacing between the metal anode and the metal cathode is 10 μm-100 μm.

2. The silicon-metal composite MEMS-based material atmospheric corrosion sensor according to claim 1, wherein the first substrate and the second substrate are respectively and independently a silicon wafer or glass.

3. The silicon-metal composite MEMS-based material atmospheric corrosion sensor according to claim 1, wherein the first substrate is a silicon wafer, the second substrate is glass, the material of the metal to be tested is stainless steel, and the material of the metal cathode is copper.

4. A preparation method for the silicon-metal composite MEMS-based material atmospheric corrosion sensor according to claim 1, comprising:
adhering the material of the metal to be tested that is sheet-shaped with the first substrate to obtain a substrate-metal composite sheet;
applying photoresist on a surface of the substrate-metal composite sheet, and then carrying out exposure, development and fixation by means of a mask with a metal anode pattern to form a metal anode target pattern; etching by mean of the metal anode target pattern until the first substrate is exposed, and removing residual photoresist to obtain a first composite sheet;
applying the photoresist on one side, with the metal anode, of the first composite sheet, then carrying out exposure, development and fixation by means of a mask with a metal cathode pattern to form a metal cathode target pattern to obtain a second composite sheet; sputtering a cathode material on the second composite sheet by using a sputtering method, and then removing residual photoresist and residual cathode material from the second composite sheet to obtain the cathode-anode module;
applying the photoresist on the first side of the second substrate, then carrying out exposure, development and fixation by means of a mask with a recess portion pattern to form a recess portion target pattern; etching by means of the recess portion target pattern until the recess portion is formed; removing residual photoresist; then applying the photoresist on the second side, carrying out exposure, development and fixation by means of a mask with a through hole pattern to form a through hole target pattern; etching by means of the through hole target pattern until the through hole is formed, and removing residual photoresist to obtain the cavity structure module; and
disposing the metal anode and the metal cathode of the cathode-anode module in the recess portion of the cavity structure module, and then connecting a surface of a second side of the first substrate to the surface of the first substrate.

5. The preparation method for the silicon-metal composite MEMS-based material atmospheric corrosion sensor according to claim 4, wherein the adhering is carried out by using a polydimethylsiloxane two-component adhesive.

6. The preparation method for the silicon-metal composite MEMS-based material atmospheric corrosion sensor according to claim 4, wherein in the step of etching by mean of the metal anode target pattern, an etching agent comprises:
2.7-5.4 mol/L of HCl, 4.4-7.4 mol/L of hydrogen peroxide, 1-10 g/L of corrosion inhibitor, 20-50 g/L of dispersing agent, and 5-10 g/L of hydrogen peroxide stabilizer.

7. The preparation method for the silicon-metal composite MEMS-based material atmospheric corrosion sensor according to claim 4, wherein the connecting comprises:
carrying out chemical cleaning and activation treatment on the surface of the second side and the surface of the first substrate by using a wet chemical treatment method; and
connecting the first substrate to a positive terminal of a power supply, connecting the second substrate to a negative terminal of the power supply, heating to 300° C.-500° C., applying a bias voltage of more than 500 V, and enabling the first substrate and the second substrate to be bonded by a generated electrostatic force.

8. Material atmospheric corrosion equipment, comprising the silicon-metal composite MEMS-based material atmospheric corrosion sensor according to claim 1.

9. The material atmospheric corrosion equipment according to claim 8, further comprising a signal processing module electrically connected to the silicon-metal composite MEMS-based material atmospheric corrosion sensor, wherein the signal processing module comprises an Application Specific Integrated Circuit (ASIC) chip with micro-current and micro-voltage detection ability.

10. The material atmospheric corrosion equipment according to claim 9, further comprising a lead frame structure capable of bearing the silicon-metal composite MEMS-based material atmospheric corrosion sensor and the ASIC chip.

11. The silicon-metal composite MEMS-based material atmospheric corrosion sensor according to claim 3, wherein the first substrate and the second substrate are respectively and independently a silicon wafer or glass.

12. The preparation method for the silicon-metal composite MEMS-based material atmospheric corrosion sensor according to claim 4, wherein the first substrate and the second substrate are respectively and independently a silicon wafer or glass.

13. The preparation method for the silicon-metal composite MEMS-based material atmospheric corrosion sensor according to claim 4, wherein the first substrate is a silicon wafer, the second substrate is glass, the material of the metal to be tested is stainless steel, and the material of the metal cathode is copper.

14. The preparation method for the silicon-metal composite MEMS-based material atmospheric corrosion sensor according to claim 12, wherein the first substrate is a silicon wafer, the second substrate is glass, the material of the metal to be tested is stainless steel, and the material of the metal cathode is copper.

15. The preparation method for the silicon-metal composite MEMS-based material atmospheric corrosion sensor according to claim 12, wherein the adhering is carried out by using a polydimethylsiloxane two-component adhesive.

16. The preparation method for the silicon-metal composite MEMS-based material atmospheric corrosion sensor according to claim 13, wherein the adhering is carried out by using a polydimethylsiloxane two-component adhesive.

17. The preparation method for the silicon-metal composite MEMS-based material atmospheric corrosion sensor according to claim 14, wherein the adhering is carried out by using a polydimethylsiloxane two-component adhesive.

18. The preparation method for the silicon-metal composite MEMS-based material atmospheric corrosion sensor according to claim 12, wherein in the step of etching by mean of the metal anode target pattern, an etching agent comprises:
2.7-5.4 mol/L of HCl, 4.4-7.4 mol/L of hydrogen peroxide, 1-10 g/L of corrosion inhibitor, 20-50 g/L of dispersing agent, and 5-10 g/L of hydrogen peroxide stabilizer.

19. The preparation method for the silicon-metal composite MEMS-based material atmospheric corrosion sensor according to claim 13, wherein in the step of etching by mean of the metal anode target pattern, an etching agent comprises:
2.7-5.4 mol/L of HCl, 4.4-7.4 mol/L of hydrogen peroxide, 1-10 g/L of corrosion inhibitor, 20-50 g/L of dispersing agent, and 5-10 g/L of hydrogen peroxide stabilizer.

20. The preparation method for the silicon-metal composite MEMS-based material atmospheric corrosion sensor according to claim 14, wherein in the step of etching by mean of the metal anode target pattern, an etching agent comprises:
2.7-5.4 mol/L of HCl, 4.4-7.4 mol/L of hydrogen peroxide, 1-10 g/L of corrosion inhibitor, 20-50 g/L of dispersing agent, and 5-10 g/L of hydrogen peroxide stabilizer.
